(19) United States
(12) Patent Application Publication
(10) Pub. No.: US 2019/0214367 A1
(43) Pub. Date: Jul. 11, 2019

(54) STACKED PACKAGE AND A MANUFACTURING METHOD OF THE SAME

(71) Applicant: Powertech Technology Inc., Hukou Township (TW)

(72) Inventors: Ming-Chih Chen, Hukou Township (TW); Hung-Hsin Hsu, Hukou Township (TW); Yuan-Fu Lan, Hukou Township (TW); Chi-An Wang, Hukou Township (TW); Hsien-Wen Hsu, Hukou Township (TW); Li-Chih Fang, Hukou Township (TW)

(73) Assignee: Powertech Technology Inc., Hukou Township (TW)

(21) Appl. No.: 15/867,613

(22) Filed: Jan. 10, 2018

(51) Int. Cl. H01L 25/065; H01L 25/00; H01L 23/28; H01L 23/538; H01L 23/552

(52) U.S. Cl. CPC H01L 25/0657; H01L 25/50; H01L 23/552; H01L 23/5384; H01L 23/28

(57) ABSTRACT

A stacked package has plurality of chip packages stacked on a base. Each chip package has an exterior conductive element formed on the active surface. Each exterior conductive element has a cut edge exposed on a lateral side of the chip package. The lateral trace is formed through the encapsulant and electrically connects to the cut edges of the chip packages. The base has an interconnect structure to form the electrical connection between the lateral trace and the external terminals. Therefore, the process for forming the electrical connections is simplified to enhance the reliability and the UPH for manufacturing the stacked package.

### BACKGROUND OF THE INVENTION

### 1. Field of the Invention

The present invention relates to a semiconductor package, and in particular to a stacked package and a manufacturing method of the same.

### 2. Description of the Prior Arts

Stacking a plurality of chips has been implemented in various semiconductor packages to achieve miniaturization of component integration. The wire bonding method and the through silicon via (TSV) with micro bump are conventional ways to provide electrical interconnection between the stacked chips and the external terminals. However, the conventional ways have following disadvantages.

When the chips are connected to the external terminals by wire bonding, the intervals between the bonding wires need to be preserved to avoid contacts between the adjacent bonding wires. The intervals inevitably increase the size of the conventional stacked package. Thus, the conventional stacked package with bonding wires does not easily achieve miniaturization. In addition, the wire bonding process takes a lot of time since all of the wires for one conventional stacked package cannot be bonded simultaneously. Therefore, the unit per hour (UPH) of the conventional stacked package manufactured by the wire bonding process is relatively low.

When the chips are connected to each other by the TSV and the micro bumps, the TSV increases stacked heights and processing complexity leading to larger package thickness and lower manufacturing yield. In addition, the requirements for the precision of alignment and locating among the micro bumps are very high. When the dimension of the conventional stacked packages become larger and larger, the position shift of the micro bumps becomes greater and greater leading to poor packaging yield.

To overcome the shortcomings, the present invention provides a stacked package and a manufacturing method of the same to mitigate or to obviate the aforementioned problems.

### SUMMARY OF THE INVENTION

The main objective of the present invention is to provide a stacked package and a manufacturing method of the same that has higher UPH and better reliability. The stacked package has plurality of chip packages stacked on a base. Each chip package has an exterior conductive element formed on the active surface. Each exterior conductive element has a cut edge exposed on a lateral side of the chip package. At least one lateral trace is formed through the encapsulant and electrically connects to the cut edges. The base has an interconnect structure to form the electrical connection between the lateral trace and the external terminals. The base may be a substrate with internal circuit or a combination of a dielectric layer and a redistribution layer. Therefore, the process for forming the electrical connections is simplified to enhance the reliability and the UPH for manufacturing the stacked package.

Other objectives, advantages and novel features of the invention will become more apparent from the following detailed description when taken in conjunction with the accompanying drawings.

### BRIEF DESCRIPTION OF THE DRAWINGS

FIG. 1A is a top view in partial section of a first embodiment of a chip package of a stacked package in accordance with the present invention;

FIG. 1B is a front view in partial section of the chip package in FIG. 1A;

FIG. 1C is a side view in partial section of the chip package in FIG. 1A;

FIG. 2A is a top view in partial section of a second embodiment of a chip package of a stacked package in accordance with the present invention;

FIG. 2B is a front view in partial section of the chip package in FIG. 2A;

FIG. 2C is a side view in partial section of the chip package in FIG. 2A;

FIG. 3A is a top view in partial section of a third embodiment of a chip package of a stacked package in accordance with the present invention;

FIG. 3B is a front view in partial section of the chip package in FIG. 3A;

FIG. 3C is a side view in partial section of the chip package in FIG. 3A;

FIGS. 4, 6, 7A, 8A, 9A, 10 and 11 are front views in partial section of a stacked package during a first embodiment of the manufacturing process in accordance with the present invention;

FIGS. 5A, 5B, 7B, 8B and 9B are top views of a structure of a stacked package during the first embodiment of a manufacturing process in accordance with the present invention;

FIG. 12A is a front view in partial section of a first embodiment of a stacked package in accordance with the present invention;

FIG. 12B is a front view in partial section of a second embodiment of a stacked package in accordance with the present invention;

FIGS. 13 to 15 are front views of a structure of a stacked package during a second embodiment of a manufacturing process in accordance with the present invention;

FIG. 16 is a front view in partial section of a third embodiment of a stacked package in accordance with the present invention;

FIG. 17 is a front view in partial section of a fourth embodiment of a stacked package in accordance with the present invention;

FIGS. 18A, 19A, 20 and 21 are front views in partial section of a stacked package during a third embodiment of the manufacturing process in accordance with the present invention;

FIGS. 18B and 19B are top views of a structure of a stacked package during the third embodiment of a manufacturing process in accordance with the present invention; and

FIG. 22 is a front view in partial section of a fifth embodiment of a stacked package in accordance with the present invention.

### DETAILED DESCRIPTION OF THE EMBODIMENTS

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

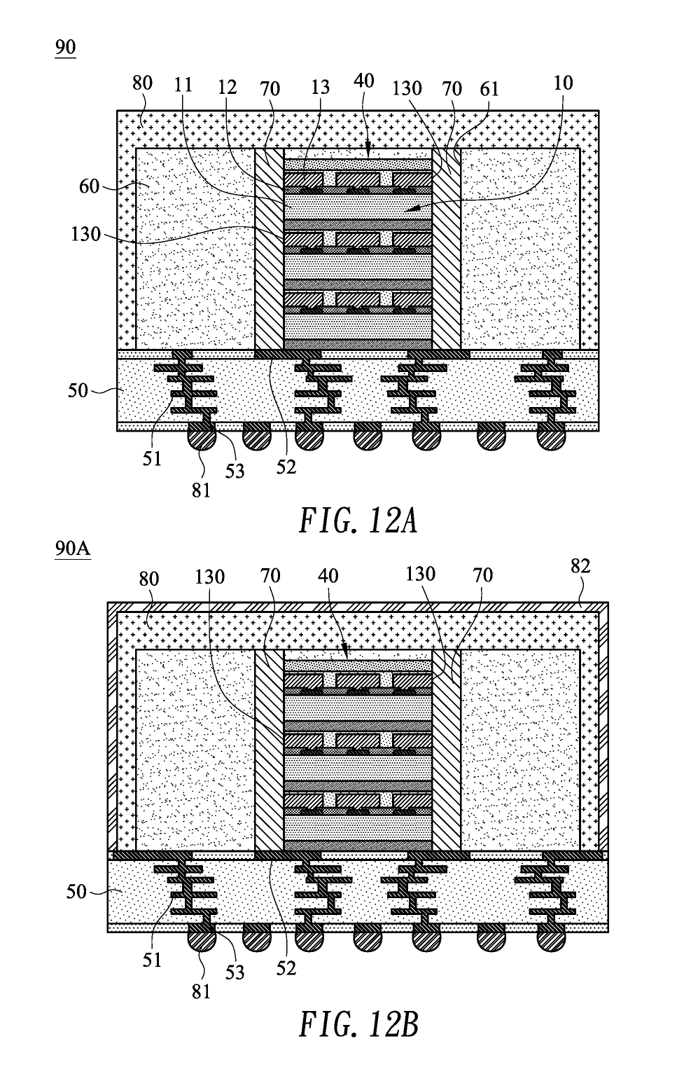

With reference to FIG. 12A, a stacked package 90 in accordance with the present invention comprises a plurality of chip packages 10. The chip package 10 has a plurality of lateral sides, a chip 11, a passivation layer 12, and a plurality of exterior conductive elements 13. The chip 11 has an active surface 111 and a back surface 112. The back surface 112 is opposite to the active surface 111. The passivation layer 12 and the exterior conductive elements 13 are formed on the active surface 111. Each exterior conductive element 13 has a cut edge 130. The cut edges 130 of the exterior conductive element 13 are exposed on a lateral side of the chip package 10. In one embodiment, the cut edges 130 of the exterior conductive element 13 are exposed on a plurality of lateral sides of the chip package 10.

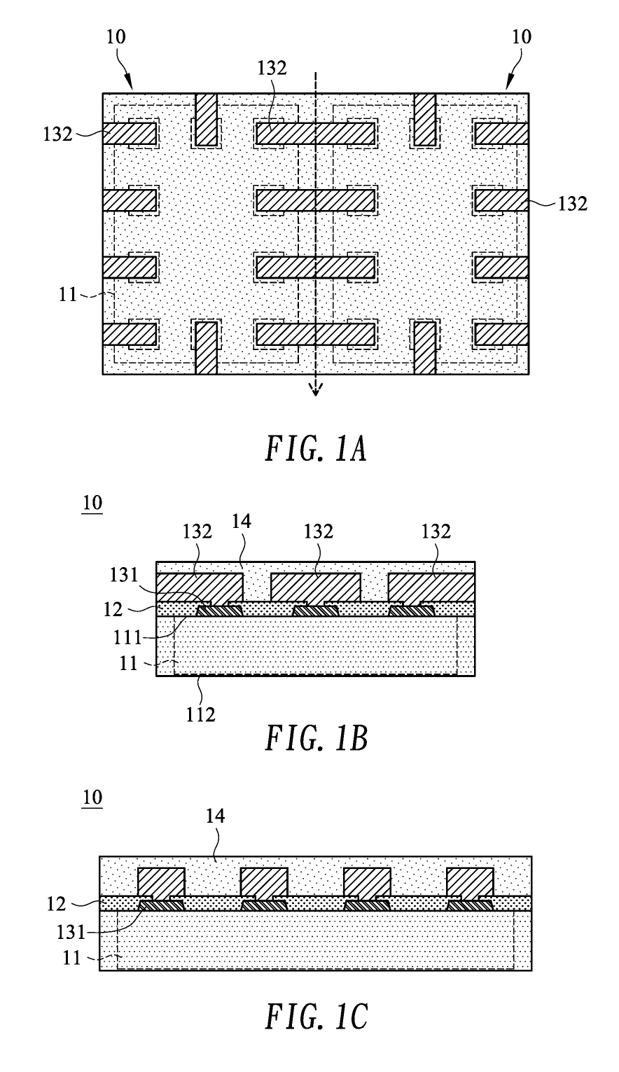

In one embodiment as shown in FIGS. 1A to 1C, the chip package 10 includes a plurality of bond pads 131, a plurality of exterior traces 132, and a chip-dielectric layer 14. Each bond pad 131 is formed on the active surface 111 and is covered by the passivation layer 12. Each exterior trace 132 is formed on a corresponding bond pad 131, extends out towards a lateral side of the chip package 10, and has an end exposed on the lateral side of the chip package 10. The chip-dielectric layer 14 is formed on the passivation layer 12 and the exterior traces 132. The chip-dielectric layer 14 may be a polyimide layer.

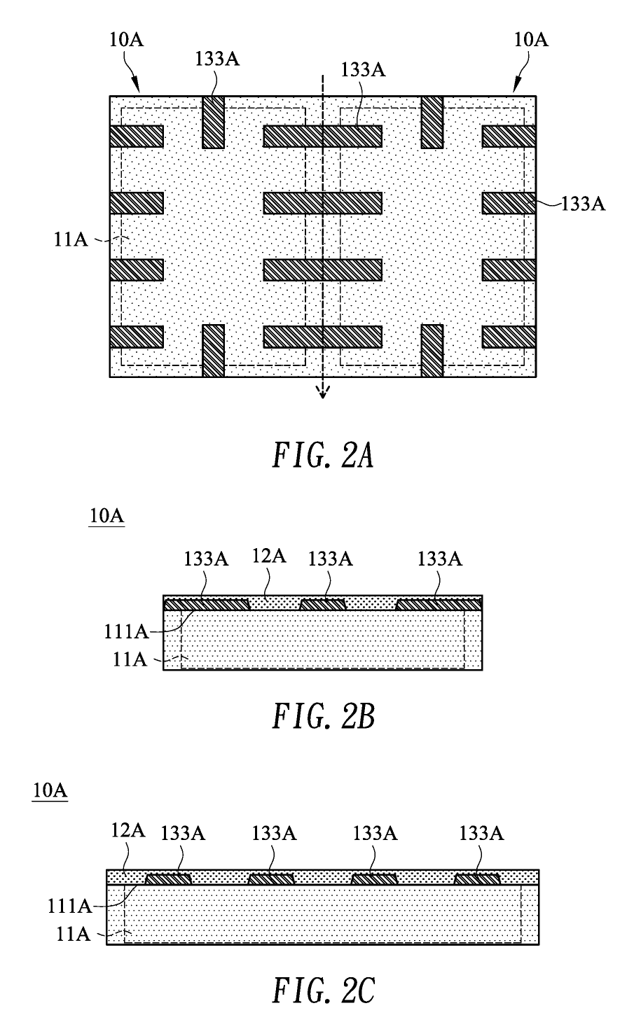

In one embodiment as shown in FIGS. 2A to 2C, the chip package 10A includes a plurality of conductive pads 133A. Each conductive pad 133A is formed on the active surface 111A of the chip 11A, is covered by the passivation layer 12A, and has an end exposed a lateral side of the chip package 10A.

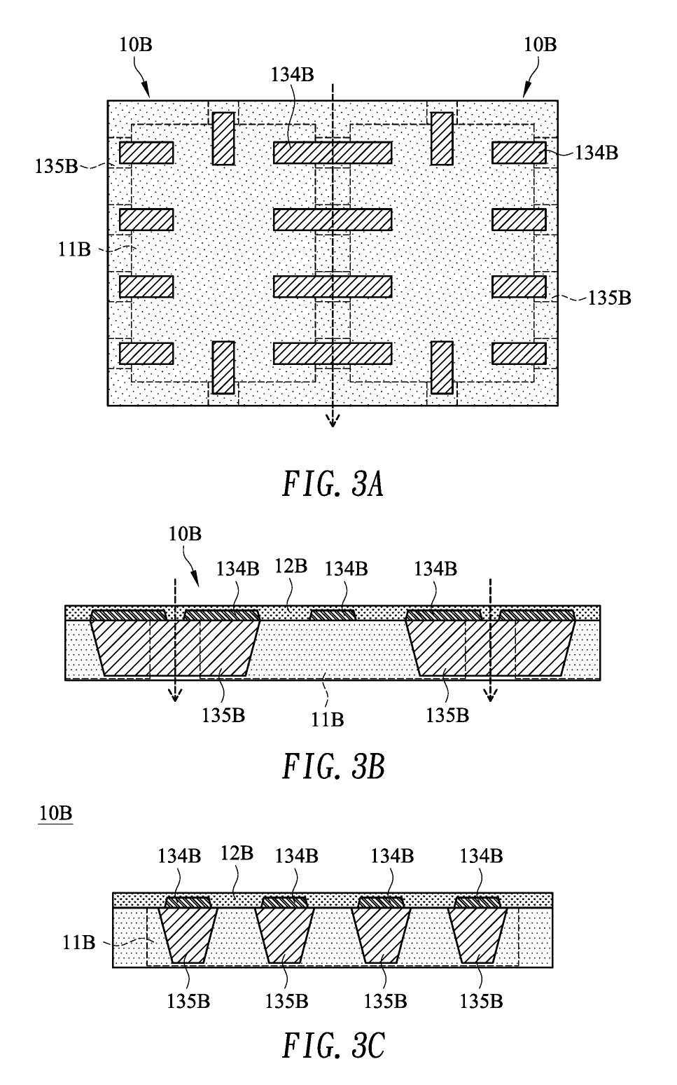

In one embodiment as shown in FIGS. 3A to 3C, the chip package 10B includes a plurality of bond pads 134B and a through silicon vias (TSVs) 135B. Each bond pad 134B is formed on the active surface 111B of the chip 11B and is covered by the passivation layer 12B. Each TSV 135B is formed in the chip 11B, is coupled to a corresponding bond pad 134B, and has an end exposed on a lateral side of the chip package 10B.

In summary, the cut edge 130 of each exterior conductive element 13 may be the exterior trace 132 as shown in FIGS. 1A to 1B, may be the conductive pad 133A as shown in FIGS. 2A to 2C, or may be the TSV 135B as shown in FIGS. 3A to 3C. The ends of the exterior traces 132 as shown in FIGS. 1A to 1B, the ends of the conductive pads 133A as shown in FIGS. 2A to 2C, and the ends of the TSVs 135B as shown in FIGS. 3A to 3C may be exposed on at least one of the lateral sides of the chip package 10, 10A, 10B.

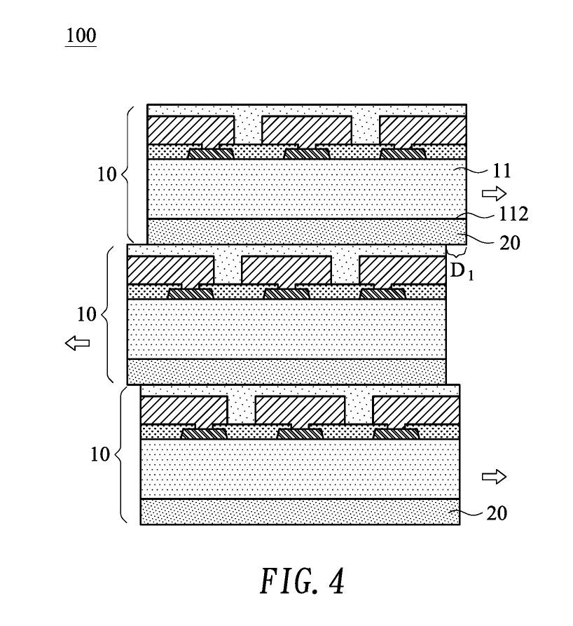

A manufacturing method of a stacked package in accordance with the present invention are illustrated from FIGS. 4 to 11 and includes, but is not limited to, following steps:

With reference to FIG. 4, a chip stack 100 are formed by stacking a plurality of chip packages 10 on top of each other. The plurality of chip packages 10 are adhered to each other by using adhesives 20 correspondingly disposed between adjacent chip packages 10. The adhesives 20 may be die attach films (DAF), epoxies, insulation pastes or the like. The chip packages 10 may align with each other through a precise alignment process or may have misalignment when alignment process has an error or is not implemented.

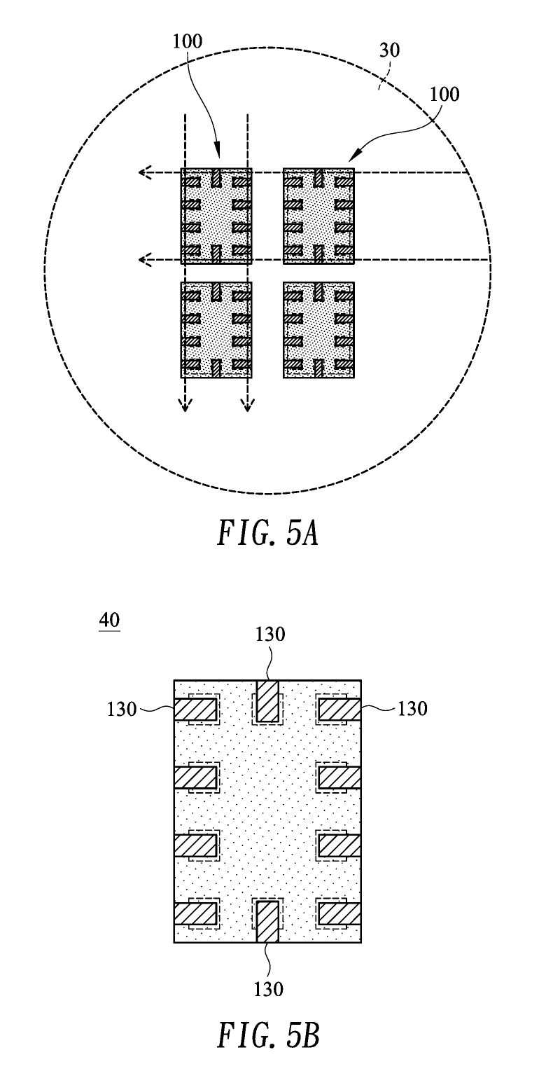

With reference to FIGS. 5A and 5B, a plurality of chip stacks 100 are encapsulated by a first encapsulant 30. The first encapsulant 30 are diced to form at least one chip encapsulation 40. The first encapsulant 30 may provide packaging protection to the chip stacks 100 to avoid electrical short and contamination and provide stability to the structure during the dicing process. In one embodiment, after the chip packages 10 are diced, the cut edges 130 on the at least one lateral side of the chip packages are exposed. In one embodiment, the chip packages 10 are diced to planarize the lateral sides of the chip packages 10 and resolve misalignment issue. The misalignment D₁ between the chip packages 10 as shown in FIG. 4 may be less than half of the pitch of the conductive element 13 to avoid deficiency after the chip stacks 100 are diced.

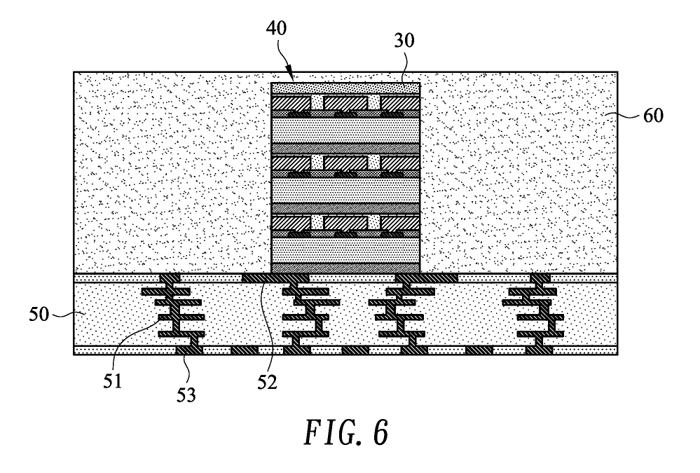

With reference to FIG. 6, the chip encapsulation 40 is arranged on a substrate 50 and is encapsulated by a second encapsulant 60. The chip encapsulations 40 can be attached on the substrate 50 The substrate 50 comprises an internal circuit 51, a plurality of upper connection pads 52, and a plurality of lower connection pads 53. The upper connection pads 52 and the lower connection pads 53 electrically connect to the internal circuit 51 and are formed on opposite sides of the substrate 50. The chip encapsulation 40 are disposed on the upper connection pads 52. The second encapsulant 60 may provide packaging protection to the chip encapsulation 40 to avoid electrical short and contamination.

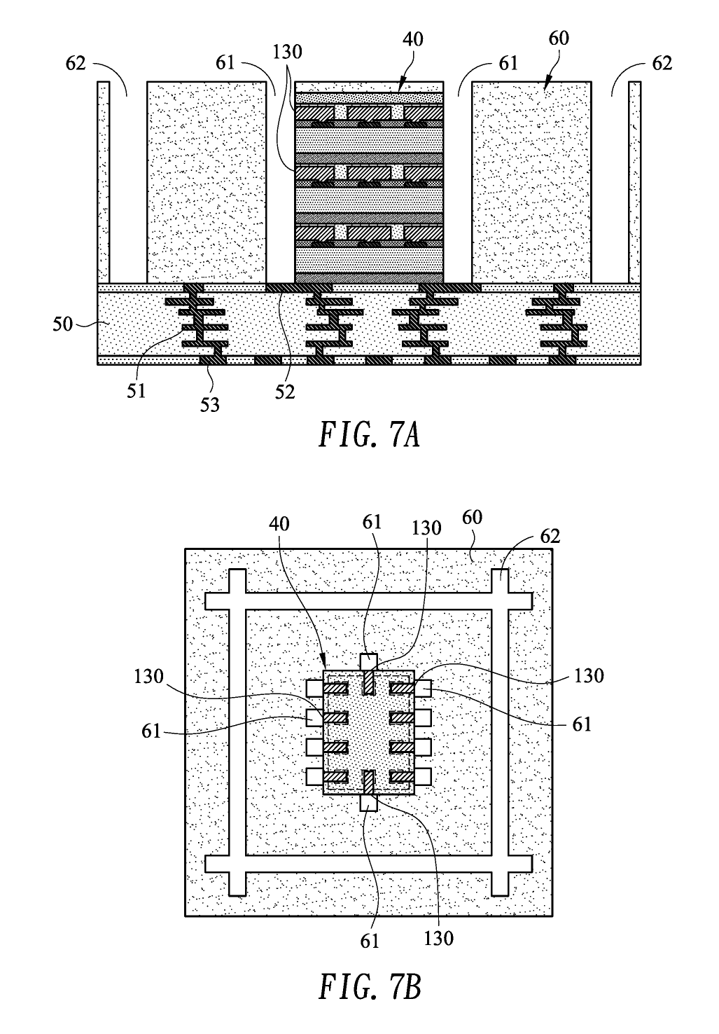

With reference to FIGS. 7A and 7B, through holes on the second encapsulant 60 may be formed to expose the cut edges 130 on the at least one lateral side. In one embodiment, the second encapsulant 60 is removed partially to form a through hole 61. The through hole 61 is formed alongside the cut edges 130 on the at least one lateral side and expose one of the upper connection pads 52 of the substrate 50. In one embodiment, a plurality of through holes 61 are formed through the second encapsulant 60. The through holes 61 are formed respectively alongside the cut edges 130 on the lateral sides and respectively expose the upper connection pads 52 of he substrate 50. In one embodiment, the second encapsulant 60 is removed through an etching process to form the through holes 61. The etching process is also used to ensure a planar surface when the cut edges 13 are exposed. In one embodiment, the second encapsulant 60 is removed partially to form at least one scribe line opening 62. The at least one scribe line opening 62 is disposed around the chip encapsulation 40.

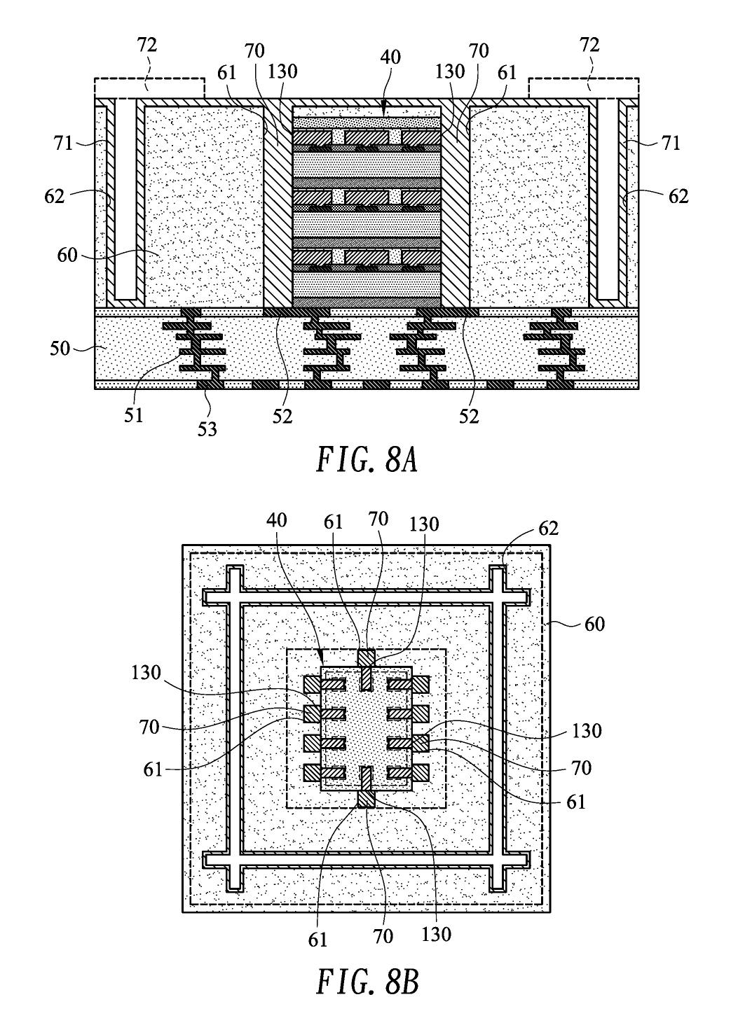

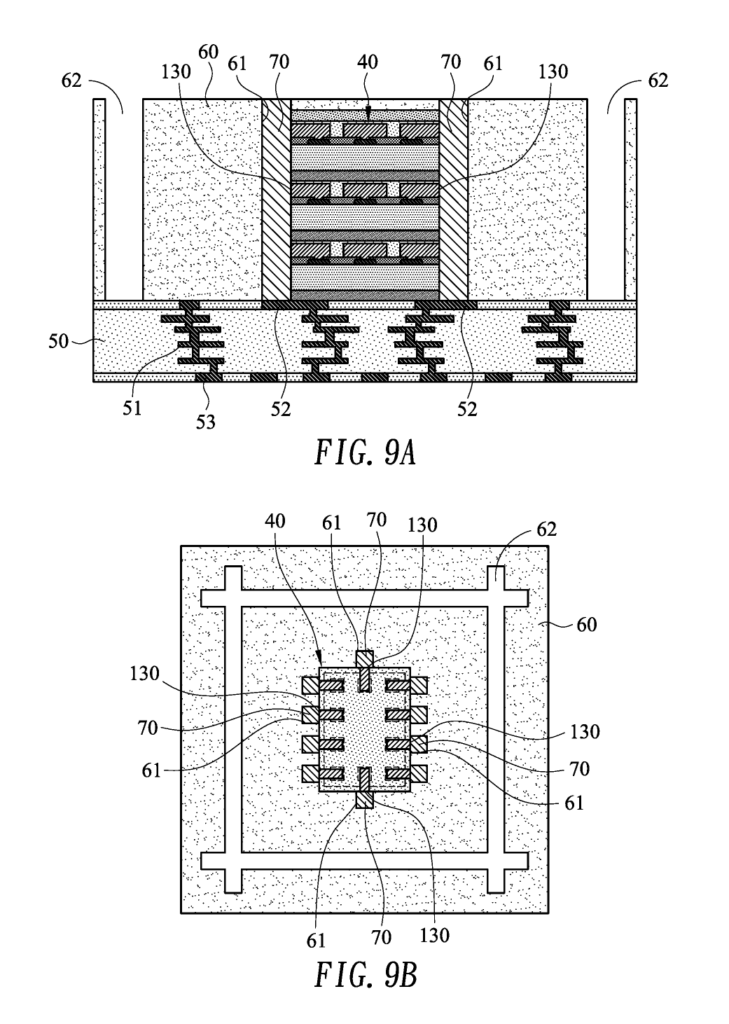

With reference to FIGS. 8A to 9B, a lateral trace 70 is formed in the through hole 61 and electrically connects the cut edges 130 to each other. In one embodiment, a plurality of lateral traces 70 are formed respectively in the through holes 61. The lateral trace 70 may be formed through sputtering, electroplating and so on. In another embodiment, a thin metal layer 71 is formed on walls of the through hole 61 and the scribe line opening 62. Then the photoresist layer 72 is used to cover the scribe line opening 62. The lateral trace 70 is then formed in the through hole 61 as shown in FIGS. 8A and 8B. The thin metal layer 71 and the lateral trace 70 may be formed by sputtering, electroplating and so on. The photoresist layer 72 is removed and an etching process is performed to remove the thin metal layer 71 in the scribe line opening 62. Since the lateral trace 70 is disposed in the through hole 61 to form a relatively thick metal trace, only a thin layer of the top of the lateral trace 70 is etched along with the thin metal layer 71.

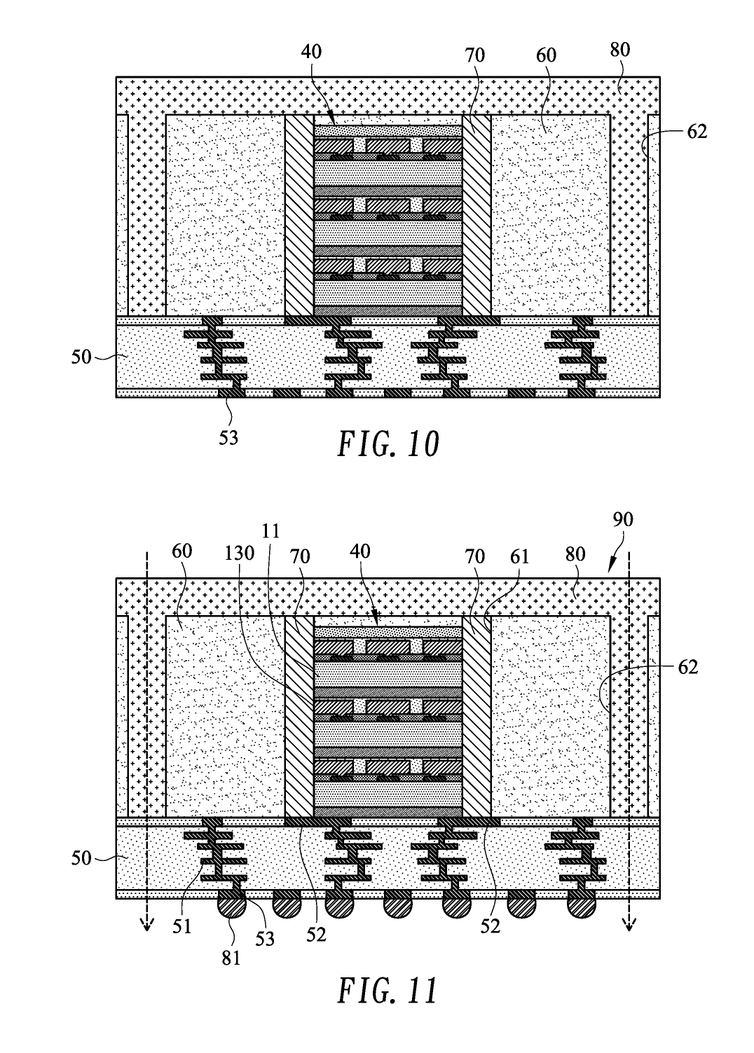

With reference to FIG. 10, the second encapsulant 60, the chip encapsulation 40, and the lateral trace 70 are encapsulated by a third encapsulant 80. In one embodiment, the scribe line opening 62 is also filled with the third encapsulant 80.

With reference to FIG. 11, a plurality of external terminals 81 are disposed respectively on the lower connection pads 53 of the substrate 50. The external terminals 81 may be a plurality of solder balls, solder pastes, contact pads, or contact pins. And, the chip encapsulations 40 are singulated along the scribe line opening 62 to form a plurality of stacked packages 90.

With the cut edges 130 exposed on the at least one lateral side, the electrical connections between the chips 11 are achieved through the lateral trace 70, the through hole 61, and the cut edges 130 on the lateral side, and the electrical connection between the chips 11 and the external terminals 81 are achieved through the substrate 50, the lateral trace 70 in the through hole 61 and the cut edges 130 on the lateral side. Thus, the process for forming the electrical connections of the manufacturing method as described is simplified to enhance the reliability and the UPH for manufacturing the stacked package as described. Moreover, the requirement of the precision for stacking the chip packages 10 is relatively low since the chip packages 10 are aligned after dicing process as shown in FIGS. 5A and 5B and the cut edges 130 are coplanar for the etching process as shown in FIGS. 7A and 7B. Therefore, the manufacturing method as described is further simplified to enhance the UPH for manufacturing the stacked package as described.

In one embodiment as shown in FIG. 12A, the stacked package 90 comprises the stacked chips 11 encapsulated by the third encapsulant 80 and the second encapsulant 60. The stacked chips 11 may be electrically connected to an external printed circuit board through the cut edges 130, the lateral trace 70, the internal circuit 51 of the substrate 50, and the external terminals 81.

In one embodiment as shown in FIG. 12B, the third encapsulant 80 is encapsulated by a metal layer 82. The metal layer 82 may electrically connect to the ground or a voltage source to provide an electromagnetic interference (EMI) shield. The metal layer 82 may be formed through sputtering.

Another embodiment of a manufacturing method of a stacked package in accordance with the present invention includes, but not limited to, following steps:

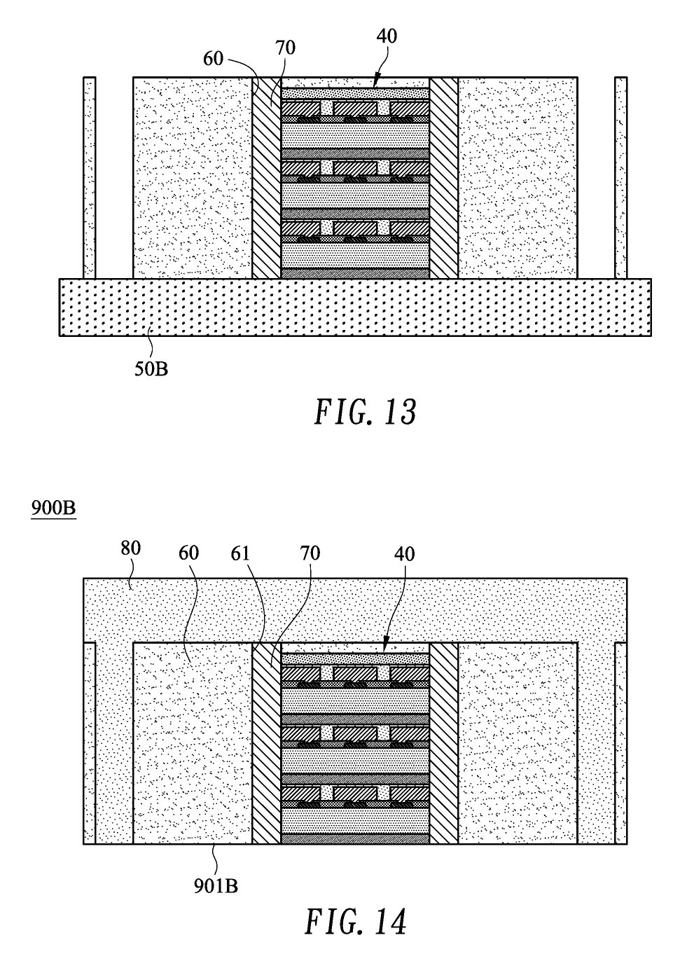

With reference to FIG. 13, the chip encapsulation 40 is disposed on a carrier 50B and is encapsulated by the second encapsulant 60. Then, the second encapsulant 60 is removed partially to expose the cut edges 130 on the lateral side and form through holes 61. the lateral trace 70 is then formed in the through hole 61. In one embodiment, the steps to partially remove the second encapsulant 60 and to form the lateral trace 70 are the same with the steps shown in FIGS. 7A to 9B.

With further reference to FIG. 14, the second encapsulant 60, the chip encapsulation 40, and the lateral trace 70 are encapsulated by the third encapsulant 80 to form a semi-finished stacked package 900B. In one embodiment, the steps to form the third encapsulant 80 is the same with the step shown in FIG. 10. Then, the carrier 50B is detached to expose a back surface 901B of the semi-finished stacked package 900B. In one embodiment, the carrier 50B is detached through a grinding process. The ends of the lateral traces 70 are exposed on the back surface 901B of the semi-finished stacked package 900B.

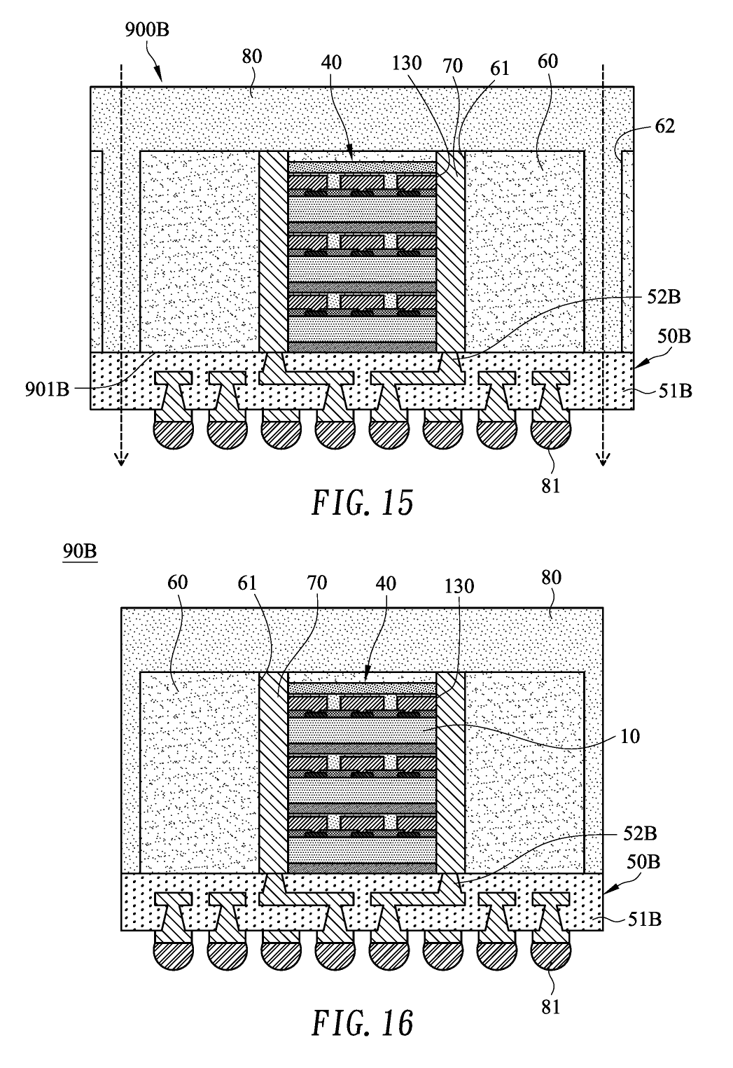

With reference to FIGS. 15 and 16, a redistribution layer 50B and a plurality of external terminals 81 are formed on the back surface 901B of the semi-finished stacked package 900B. The redistribution layer 50B electrically connects the lateral trace 70 and the external terminals 82. The redistribution layer 50B comprises the dielectric layer 51B and the circuitry 52B. The circuitry 52B are formed by conductive metals. In one embodiment, the circuitry 52B may be a multi-layer metal stack such as Titanium (Ti)/Copper (Cu)/Copper (Cu) or Titanium (Ti)/Copper (Cu)/Copper (Cu)/Nickel (Ni)/gold (Au). In one embodiment, the dielectric layer 51B may be a polyimide layer used to encapsulate and insulate the multi-layer metal stack of the circuitry 52B. In one embodiment, the dielectric layer 51B includes a first dielectric layer and a second dielectric layer formed respectively above and under the circuitry 52B. In one embodiment, an under bump metallurgy (UBM) layer is formed between and electrically connects to the redistribution layer 52B and the external terminals 81. The number of the metal layers of the circuitry 52B and the number of the dielectric layer 51B are not limited to the embodiment as described and can be selectively designed. A singulation process is then performed to form a stacked package 90B.

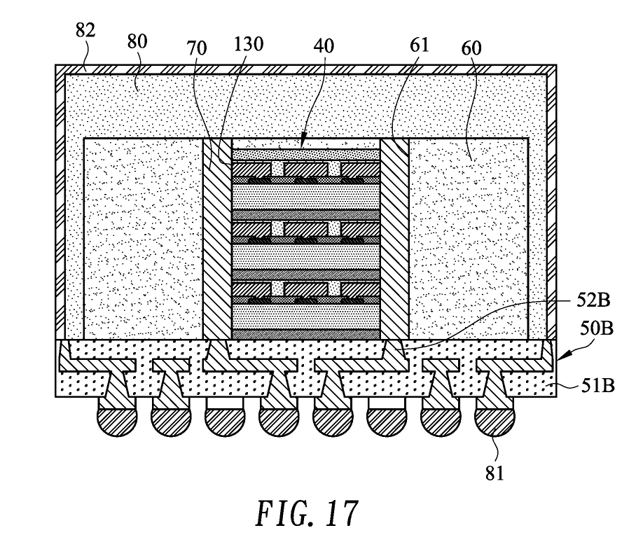

In one embodiment as shown in FIG. 17, the third encapsulant 80 is encapsulated by the metal layer 82. The metal layer 82 may be electrically connected to the ground or a voltage source to provide an EMI shield.

Yet another embodiment of a manufacturing method of a stacked package in accordance with the present invention includes, but not limited to, following steps:

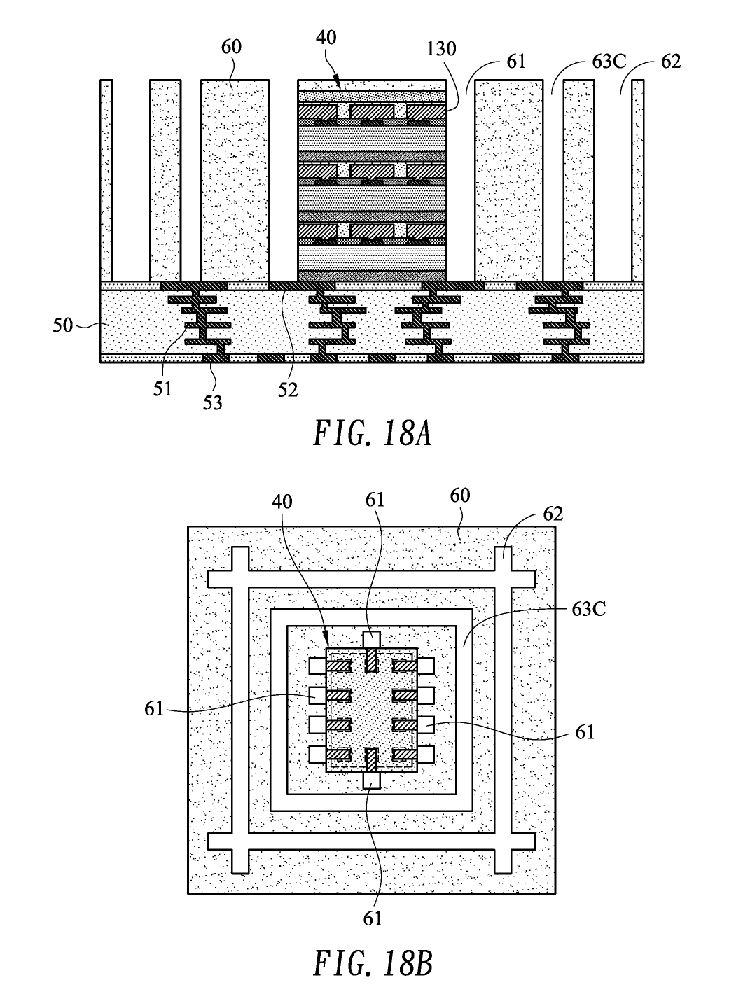

The second encapsulant 60 is removed partially to form a through hole 61, a scribe line opening 62, and an EMI opening 63C as shown in FIGS. 18A and 18B after the step as shown in FIG. 6 is performed. The EMI opening 63C may surround the chip encapsulation 40.

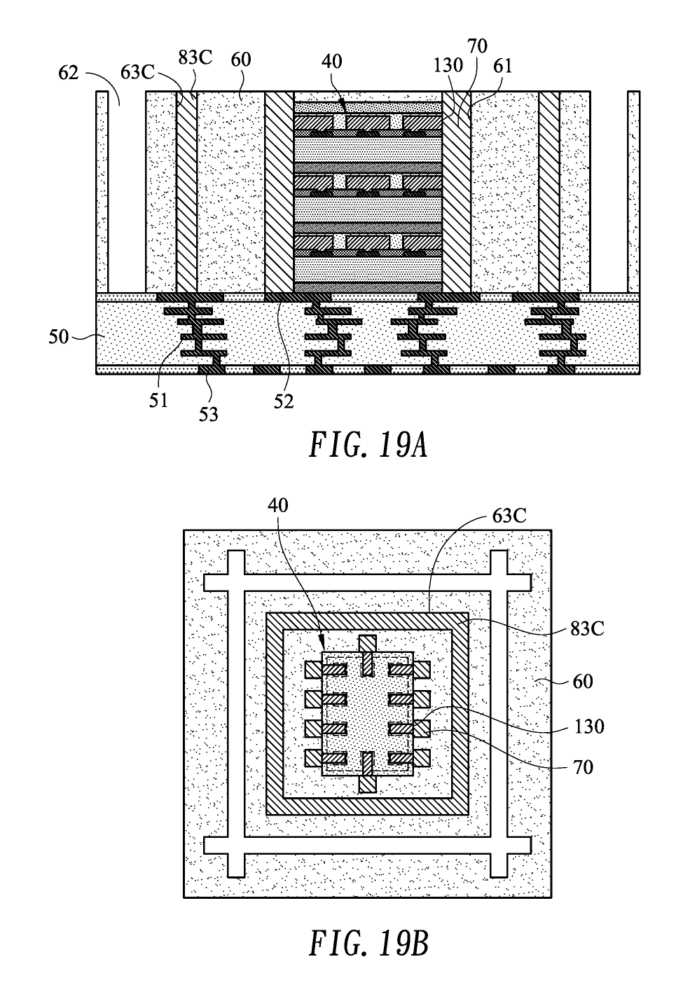

With reference to FIGS. 19A and 19B, a lateral trace 70 is formed in the through hole 61 and electrically connects the upper connection pad 52 and the cut edges 130. A conductive trace 83C is formed in the EMI opening 63C and electrically connects to the ground signal of the substrate 50.

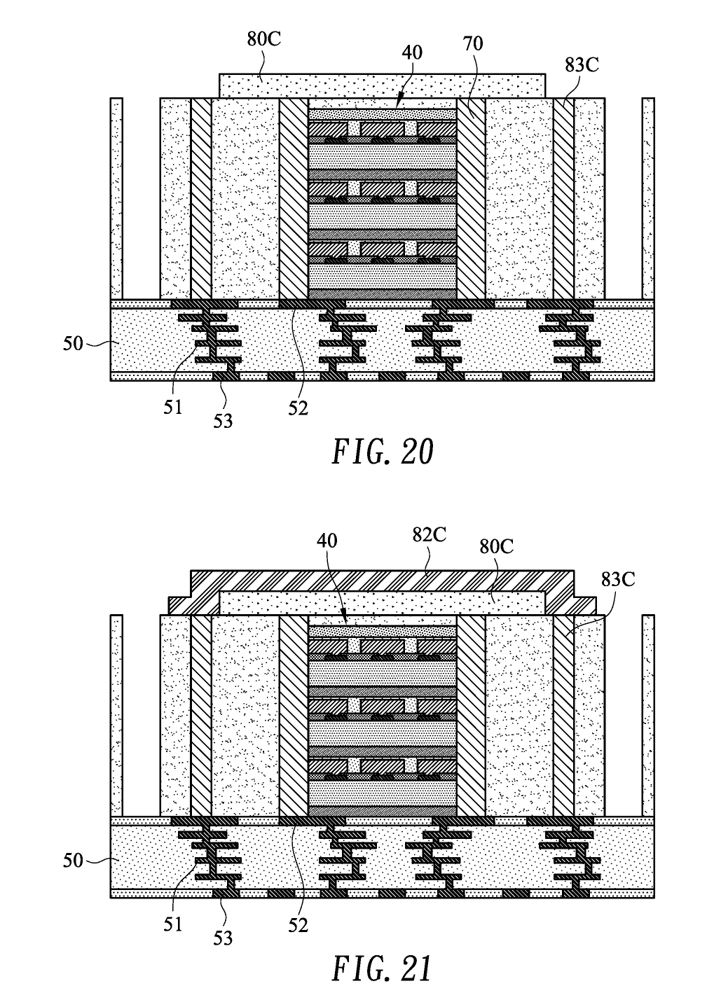

With reference to FIG. 20, the chip encapsulation 40 and the lateral trace 70 are covered by the third encapsulant 80C.

With reference to FIG. 21, a metal layer 82C is formed on the third encapsulant 80C and electrically connects to the conductive trace 83C. In one embodiment, the conductive trace 83C and the metal layer 82C may be formed by sputtering.

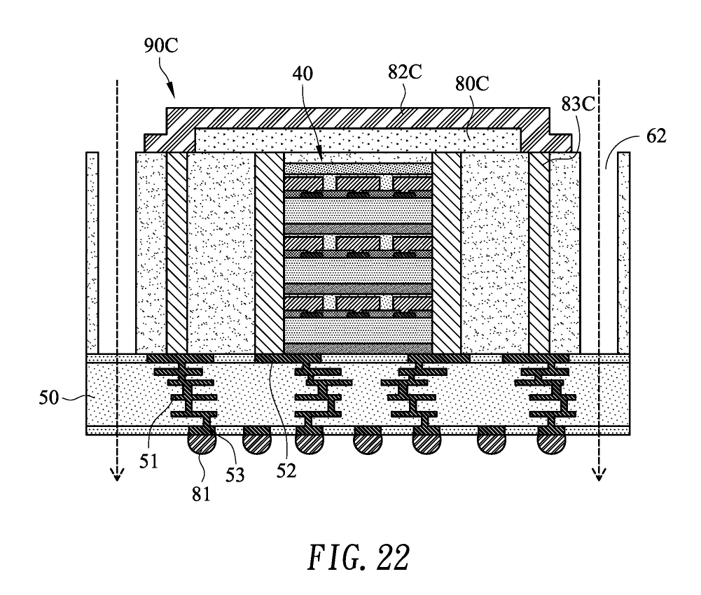

With reference to FIG. 22, a plurality of external terminals 81 are disposed respectively on the lower connection pads 53 of the substrate 50. Then the chip encapsulations 40 are singulated along the scribe line opening 62 to form a plurality of stacked packages 90C. In one embodiment, the stacked package 90C with the conductive trace 83C and the metal layer 82C may have the at least one redistribution layer and the at least one dielectric layer to substitute the substrate.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A stacked package comprising:
a plurality of chip packages stacked on each other, each of the plurality of chip packages comprises:
a chip having an active surface and a back surface opposite to the active surface;
a passivation layer formed on the active surface of the chip; and
a plurality of exterior conductive elements formed on the active surface of the chip and electrically connected to the chip, and each exterior conductive element having a cut edge exposed on a lateral side of the chip package;
a plurality of adhesives attached respectively between adjacent chip packages;
a first encapsulant encapsulating the chip packages and having a through hole formed along the cut edges of the chip packages;
a lateral trace formed in the through hole of the first encapsulant to electrically connect the cut edges of the chip packages; and
a base attached to a bottom chip package of the plurality of chip packages and a bottom of the first encapsulant and having an interconnect structure electrically connecting to the lateral trace.

2. The stacked package as claimed in claim 1 further comprising a second encapsulant encapsulating the first encapsulant and the lateral trace.

3. The stacked package as claimed in claim 1, wherein
the base comprises a substrate;
the interconnect structure of the base is formed in the substrate and comprises
an internal circuit;
a plurality of upper connection pads electrically connecting to the internal circuit and the lateral trace; and
a plurality of lower connection pads electrically connecting to the internal circuit; and
a plurality of external terminals are formed on a bottom of the substrate and electrically connecting to the lower connection pads.

4. The stacked package as claimed in claim 1, wherein
the interconnect structure of the base comprises a redistribution layer electrically connecting to the lateral trace; and
a plurality of external terminals are formed on a bottom of the redistribution layer and electrically connecting to the redistribution layer

5. The stacked package as claimed in claim 1 further comprising:
a metal layer encapsulating the first encapsulant.

6. The stacked package as claimed in claim 1 further comprising:
a third encapsulant covering the lateral trace;
an electromagnetic interference (EMI) opening formed on the encapsulant and disposed around the stacked chip packages;
a conductive trace formed in the EMI opening; and
a metal layer formed on the third encapsulant and electrically connects to the conductive trace.

7. The stacked package as claimed in claim 1, wherein
each exterior conductive element comprises:
a bond pad formed on the active surface and encompassed in the passivation layer; and
an exterior trace formed on the bond pad, extending away from the bond pad, wherein the cut edge is a terminal of the exterior trace exposed on the lateral side; and
the chip package further comprises:
a dielectric layer formed on the passivation layer and the exterior trace.

8. The stacked package as claimed in claim 1, wherein each exterior conductive element comprises a bond pad formed on the active surface, extending away from the center of the active surface, and encompassed in the passivation layer, wherein the cut edge is a terminal of the bond pad exposed on the lateral side.

9. The stacked package as claimed in claim 1, wherein each exterior conductive element comprises:
a bond pad formed on the active surface and encompassed in the passivation layer; and
a through silicon via formed in the chip, connecting to the bond pad, wherein the cut edge is a terminal of the through silicon via exposed on the lateral side.

10. A manufacturing method of a stacked package comprising steps of:
providing a plurality of chip packages, wherein each of the plurality of chip packages comprises:
a chip having an active surface and a back surface opposite to the active surface;
a passivation layer formed on the active surface of the chip; and
a plurality of exterior conductive elements formed on the active surface of the chip and electrically connected to the chip, and each exterior conductive element having a cut edge exposed on a lateral side of the chip packages;
providing a substrate, wherein the substrate comprises:
an internal circuit; and
a plurality of upper connection pads and a plurality of lower connection pads electrically connecting to the internal circuit;
stacking the chip packages on the substrate, wherein the back surface of one chip package faces the active surface of the adjacent chip package, a plurality of adhesives are attached respectively between adjacent chip packages and the substrate attached to a bottom chip package of the plurality of chip packages;
encapsulating the chip packages on the substrate by a first encapsulant;
forming a through hole through the first encapsulant to expose the cut edges of the chip packages;
forming a lateral trace in the through hole to electrically connect the cut edges of the chip packages and the upper connection pads of the substrate and
performing singulation to form a stacked package.

11. The manufacturing method as claimed in claim 10 further comprising a step of encapsulating the first encapsulant and the lateral trace by a second encapsulant after forming the lateral trace.

12. The manufacturing method as claimed in claim 10, wherein in the step of forming the through hole further comprises steps of forming a scribe opening through the first encapsulant, wherein the through hole is disposed between the scribe line opening and the chip packages.

13. The manufacturing method as claimed in claim 12, wherein in the step of forming the lateral trace comprises steps of:
forming a thin metal layer on walls of the through hole and the scribe line opening;
covering the scribe line opening by a photoresist layer;
forming the lateral trace in the through hole;
removing the photoresist layer; and
etching the thin metal layer in the scribe line opening.

14. The manufacturing method as claimed in claim 11 further comprising step of encapsulating the second encapsulant by a metal layer.

15. The manufacturing method as claimed in claim 10, wherein
in the step of forming the through hole further comprises step of forming an EMI opening through the first encapsulant and disposed around the chip packages;
in the step of forming the lateral trace further comprises step of forming a conductive trace in the EMI opening; and
after the step of forming the lateral trace further comprises steps of: forming a third encapsulant to cover the lateral trace and forming a metal layer on the third encapsulant, wherein the metal layer connects to the conductive trace.

16. The manufacturing method as claimed in claim 10 further comprising a step of forming a plurality of external terminals respectively on the lower connection pads of the substrate before performing singulation.

17. A manufacturing method of a stacked package comprising steps of:
providing a plurality of chip packages, wherein each of the plurality of chip packages comprises:
a chip having an active surface and a back surface opposite to the active surface;
a passivation layer formed on the active surface of the chip; and
a plurality of exterior conductive elements formed on the active surface of the chip and electrically connected to the chip, and each exterior conductive element having a cut edge exposed on a lateral side of the chip packages;
stacking the chip packages on a carrier, wherein the back surface of one chip package faces the active surface of the adjacent chip package, a plurality of adhesives are attached respectively between adjacent chip packages and the carrier attached to a bottom chip package of the plurality of chip packages;
encapsulating the chip packages on the carrier by a first encapsulant;
forming a through hole through the first encapsulant to expose the cut edges of the chip packages;
forming a lateral trace in the through hole to electrically connect the cut edges of the chip packages;
detaching the carrier to expose an end of the lateral trace;
forming a redistribution layer to electrically connect to the end of the lateral trace; and
performing singulation to form a stacked package.

18. The manufacturing method as claimed in claim 17 further comprising a step of encapsulating the first encapsulant and the lateral trace by a second encapsulant after forming the lateral trace.

19. The manufacturing method as claimed in claim 17, wherein in the step of forming the through hole further comprises steps of forming a scribe opening through the first encapsulant, wherein the through hole is disposed between the scribe line opening and the chip packages.

20. The manufacturing method as claimed in claim 19, wherein in the step of forming the lateral trace comprises steps of:
forming a thin metal layer on walls of the through hole and the scribe line opening;
covering the scribe line opening by a photoresist layer;
forming the lateral trace in the through hole;
removing the photoresist layer; and
etching the thin metal layer in the scribe line opening.
